(19) United States
(12) Patent Application Publication
(10) Pub. No.: US 2026/0165078 A1
(43) Pub. Date: Jun. 11, 2026

(54) SUBSTRATE TRANSFER APPARATUS, SUBSTRATE TRANSFER METHOD, AND COMPUTER-READABLE STORAGE MEDIUM

(71) Applicant: Tokyo Electron Limited, Tokyo (JP)

(72) Inventors: Tomohiro NODA, Kumamoto (JP); Shunya OTAKI, Kumamoto (JP)

(21) Appl. No.: 19/412,210

(22) Filed: Dec. 8, 2025

(30) Foreign Application Priority Data
Dec. 10, 2024 (JP) 2024-215902

(51) Int. Cl. H10P 72/30; H10P 72/00

(52) U.S. Cl. CPC H10P 72/3302; H10P 72/0602; H10P 72/0606

(57) ABSTRACT

There is provided a substrate transfer apparatus for transferring a substrate to a rotation processor provided in a housing provided in common with at least one heat treater configured to perform a heat treatment on the substrate and configured to perform processing on the substrate while holding and rotating the substrate. The substrate transfer apparatus includes a transfer arm configured to support and move the substrate, and a controller configured to control an operation of the transfer arm. The controller acquires first and second eccentric positions of the substrate held by the rotation processor with respect to a rotational center of the rotation processor based on maximum and minimum temperatures which are set as processing temperatures of the at least one heat treater, and adjusts a position of the transfer arm when delivering the substrate to the rotation processor based on the first and the second eccentric positions.

### CROSS-REFERENCE TO RELATED APPLICATION

This application is based upon and claims the benefit of priority from Japanese Patent Application No. 2024-215902, filed on Dec. 10, 2024, the entire contents of which are incorporated herein by reference.

### TECHNICAL FIELD

The present disclosure relates to a substrate transfer apparatus, a substrate transfer method, and a non-transitory computer-readable storage medium.

### BACKGROUND

Patent Document 1 discloses a technique for stopping a transfer mechanism at a target position.

### PRIOR ART DOCUMENTS

### Patent Documents

Patent Document 1: Japanese Laid-Open Patent Publication No. 2013-230036

### SUMMARY

According to one embodiment of the present disclosure, there is provided a substrate transfer device for transferring a substrate to a rotation processor provided in a housing provided in common with at least one heat treater configured to perform a heat treatment on the substrate and configured to perform processing on the substrate while holding and rotating the substrate. The substrate transfer device includes: a transfer arm configured to support and move the substrate; and a controller configured to control an operation of the transfer arm, wherein the controller acquires first and second eccentric positions of the substrate held by the rotation processor with respect to a rotational center of the rotation processor based on maximum and minimum temperatures which are set as processing temperatures of the at least one heat treater, and adjusts a position of the transfer arm when delivering the substrate to the rotation processor based on the first eccentric position and the second eccentric position.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view showing a schematic configuration of a coating-developing apparatus as a substrate processing system including a substrate transfer device according to an embodiment.

FIG. 2 is a view showing a schematic configuration of a central portion of the coating-developing apparatus in a depth direction.

FIG. 3 is a view showing a schematic configuration of a first stacked processing block.

FIG. 4 is a view showing a schematic configuration of a resist film forming module.

FIG. 5 is a view showing a schematic configuration of a heating module.

FIG. 6 is a side view showing a schematic configuration of a main transfer mechanism.

FIG. 7 is a functional block diagram of a controller according to a first embodiment, which shows transferring a wafer to the resist film forming module which is a rotary processing apparatus.

FIG. 8 is a flowchart illustrating an example of a flow of adjusting a delivery position according to the first embodiment.

FIG. 9 is a functional block diagram of a controller according to a second embodiment, which shows transferring the wafer to the resist film forming module.

FIG. 10 is a flowchart illustrating an example of a flow of adjusting a delivery position according to the second embodiment.

FIG. 11 is a plan view showing a schematic configuration of a modification of the coating-developing apparatus including the substrate transfer device according to an embodiment.

FIG. 12 is a view showing a schematic internal configuration on a front side of the coating-developing apparatus.

FIG. 13 is a view showing a schematic internal configuration on a rear side of the coating-developing apparatus.

FIG. 14 is a longitudinal side view showing a schematic internal configuration of the coating-developing apparatus.

FIG. 15 is a side view of a transfer mechanism.

### DETAILED DESCRIPTION

Hereinafter, a substrate transfer device and a substrate transfer method according to the present embodiment will be described with reference to the accompanying drawings.

Throughout this specification disclosure and the drawings, elements having substantially the same functional configuration will be denoted by the same reference numerals, and redundant descriptions thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Coating-Developing Apparatus>

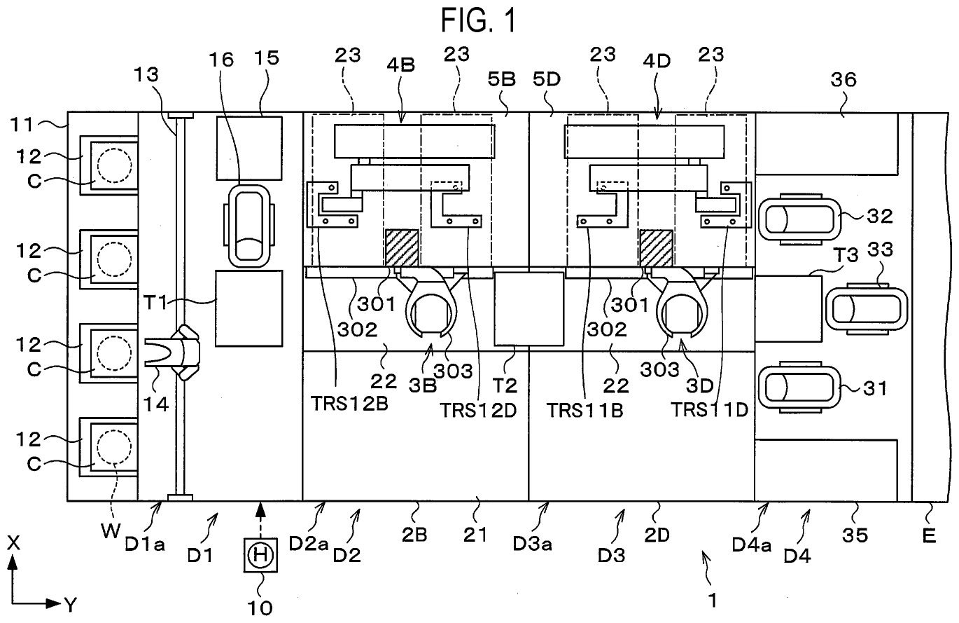

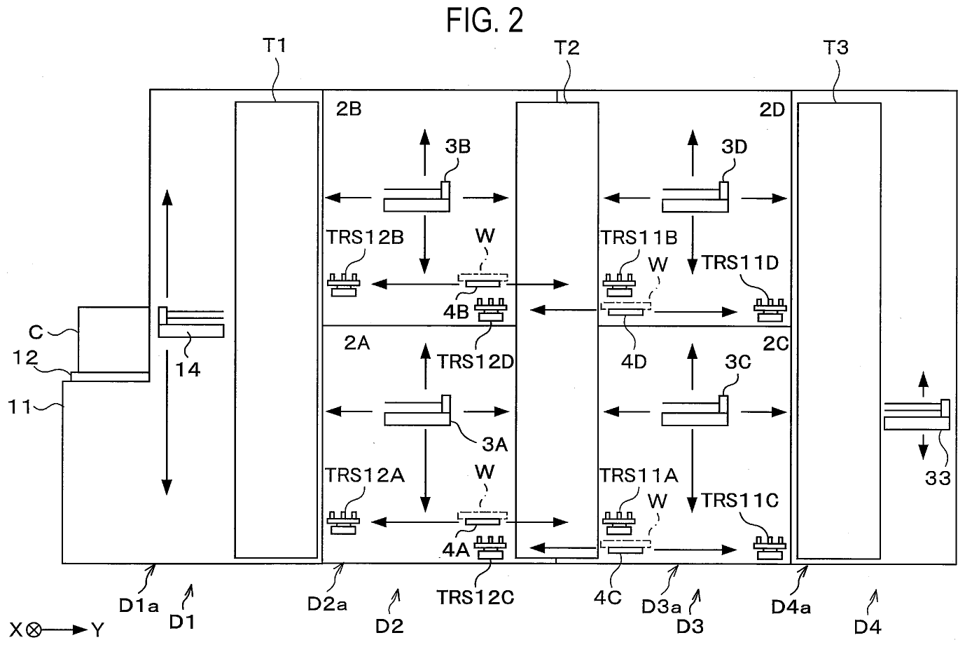

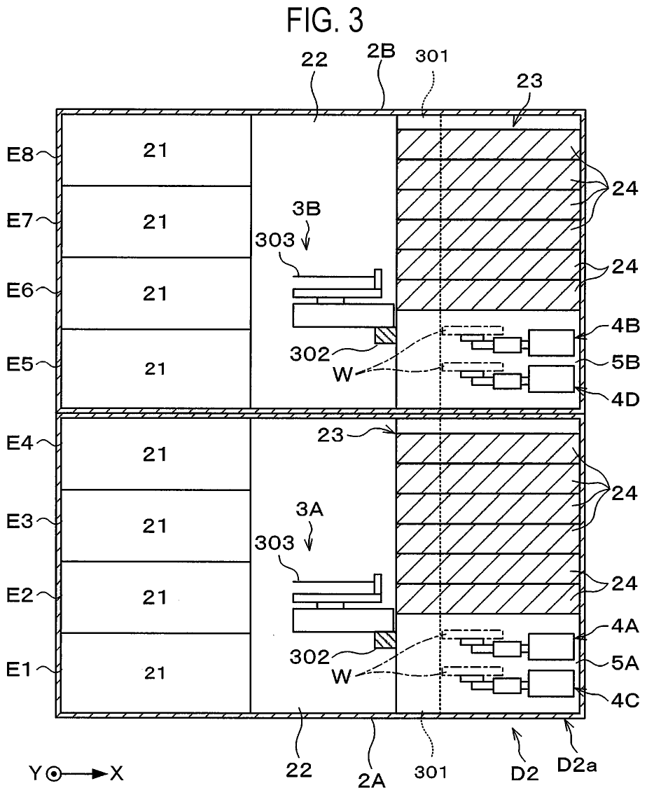

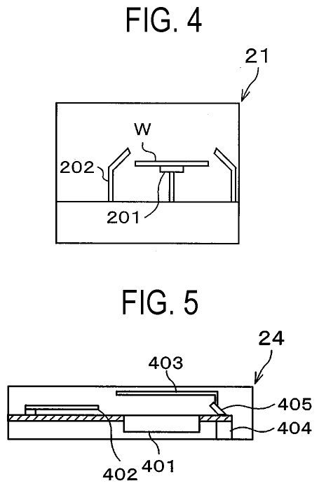

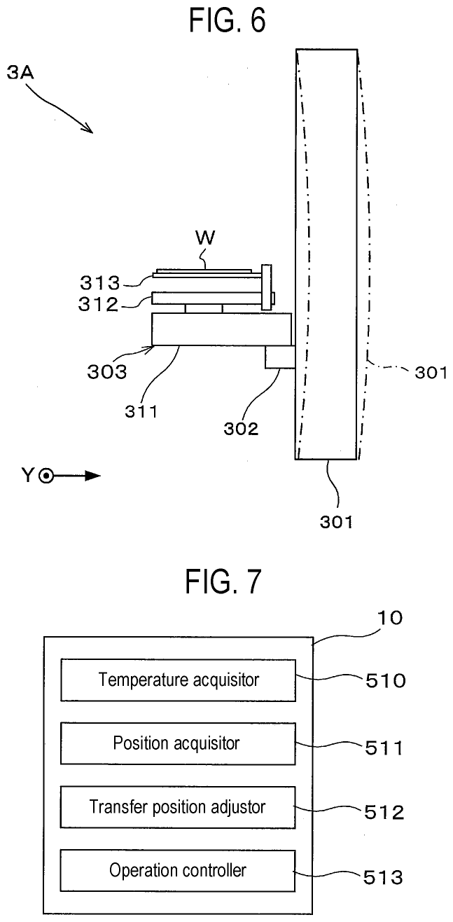

FIG. 1 is a plan view showing a schematic configuration of a coating-developing apparatus 1 as a substrate processing system including a substrate transfer device according to an embodiment. FIG. 2 is a view showing a schematic configuration of a central portion of the coating-developing apparatus 1 in a depth direction (X direction). FIG. 3 is a view showing a schematic configuration of a first stacked processing block to be described later. FIG. 4 is a view showing a schematic configuration of a resist film forming module 21 to be described later. FIG. 5 is a view showing a schematic configuration of a heating module 24 to be described later. FIG. 6 is a side view showing a schematic configuration of a main transfer mechanism 3A to be described later.

As shown in FIGS. 1 and 2, the coating-developing apparatus 1 includes a carrier block D1, a first stacked processing block D2, a second stacked processing block D3, and an interface block D4 which are arranged in the named order in a width direction (Y direction in FIG. 1 and the like). In the carrier block D1, the first stacked processing block D2, the second stacked processing block D3, and the interface block D4, adjacent blocks are connected to each other. Further, the carrier block D1, the first stacked processing block D2, the second stacked processing block D3, and the interface block D4 include housings D1a, D2a, D3a, and D4a, respectively, and are separated from one another by the housings D1a, D2a, D3a, and D4a. Transfer regions for semiconductor wafers (hereinafter, referred to as “wafers”) W, which are substrates, are formed inside each of the housings D1a, D2a, D3a, and D4a.

An exposure apparatus E is connected to a side of the interface block D4 opposite the second stacked processing block D3 (a positive side in the Y direction).

The wafers W are transferred to the coating-developing apparatus 1 while being stored in a carrier C, for example, a so-called FOUP (Front Opening Unify Pod). Each of the first stacked processing block D2 and the second stacked processing block D3 are divided into two sections in a vertical direction. Each of the sections constitutes a processing block including a processing module and a main transfer mechanism for transferring the wafer W to the processing module. Hereinafter, lower and upper sections of the first stacked processing block D2 which is divided into two sections in the vertical direction, will be referred to as a processing block 2A and a processing block 2B, respectively. Similarly, lower and upper sections of the second stacked processing block D3 which is divided into two sections in the vertical direction, will be referred to as a processing block 2C and a processing block 2D, respectively.

The processing blocks 2A and 2C are adjacent to each other in the width direction (the Y direction), which is a horizontal direction. The processing blocks 2A and 2C may be collectively referred to as a lower processing block. Further, the processing blocks 2B and 2D are adjacent to each other in the width direction (the Y direction) as the horizontal direction. The processing blocks 2B and 2D may be collectively referred to as an upper processing block. FIG. 1 shows the upper processing block. Each of the processing blocks 2B and 2D, which are the upper processing block, includes a shuttle (also referred to as a bypass transfer mechanism). The shuttle transfers the wafer W toward a block on the downstream side of a transfer path without going through the processing modules.

The “module” used herein refers to a location other than the transfer mechanism (including the shuttle), at which the wafers W are placed. A module that performs processing on the wafers W is referred to as the processing module as described above. Such processing also includes acquiring images for inspection.

The carrier block D1 includes a carrier stage 11 at an end portion thereof opposite the first stacked processing block D2 (the negative side in the Y direction in FIGS. 1 and 2). The carrier stage 11 includes a plurality of placement plates 12 on which carriers C are placed when loading/unloading the carriers C into/from the coating-developing apparatus 1. The plurality of placement plates 12 are arranged in the depth direction (the X direction in FIG. 1, and the like).

Further, the carrier block D1 includes a delivery tower T1 provided in the center thereof in the depth direction (the X direction) at its end portion near the first stacked processing block D2 (the positive side in the Y direction in FIG. 1, and the like). The delivery tower T1 is configured such that modules such as delivery modules on which the wafers W are temporarily placed, are stacked in multiple stages in the vertical direction.

Further, the carrier block D1 includes a transfer mechanism 14 provided in the center of the width direction (the Y direction) as the horizontal direction, which is movable on a transfer path 13 extending in the depth direction (X direction). The transfer mechanism 14 is movable in the vertical direction and around the vertical axis (the 0 direction), and may transfer the wafers W between the carriers C on the placement plates 12 and the modules in the delivery tower T1.

Further, a hydrophobization treatment module 15 that performs a hydrophobization treatment on the wafers W is provided at a rear end side of the carrier block D1 in back of the delivery tower T1 (the positive side in the X direction in FIG. 1, and the like). A hydrophobization treatment modules 15 may be stacked one above another vertically in multiple stages.

Further, a transfer mechanism 16 is provided in the carrier block D1 between the delivery tower T1 and the hydrophobization treatment module 15. The transfer mechanism 16 is movable in the vertical direction and around the vertical axis (the 0 direction) and may transfer the wafers W between the modules in the delivery tower T1 and the hydrophobization treatment module 15, between the modules in the delivery tower T1, and the like The transfer mechanism 16 may also transfer the wafers W to a delivery module TRS12B for a shuttle 4B provided in the processing block 2B.

As shown in FIG. 3, in the first stacked processing block D2, resist film forming module 21 serving as liquid processing modules are stacked one above another in multiple stages (for example, four or more stages, eight stages in the illustrated example) on the front side (the negative side in the X direction). Specifically, a front portion of the first stacked processing block D2 is divided into multiple (for example, four or more, eight in the illustrated example) layers along the vertical direction. The resist film forming module 21 is provided in each layer. Hereinafter, the eight layers will be referred to as layers E1 to E8 in order from the bottom. The layers E1 to E4 on the lower side are included in the processing block 2A, and the layers E5 to E8 on the upper side are included in the processing block 2B.

As shown in FIGS. 1 and 3, a transfer region 22 for the wafer W is provided in back of (the positive side in the X direction) of the layers E5 to E8 of the processing block 2B. The transfer region 22 is formed in a belt shape in a plan view, which extends from one end to the other end of the processing block 2B in the width direction (the Y direction), and is formed across the layers E5 to E8 in the vertical direction. A processing module stack 23 formed by stacking processing modules one above another in multiple stages (six stages in the illustrated example) is provided at the rear side (the positive side in the X direction) of the transfer region 22. Two processing module stacks 23 are provided to be spaced apart from each other in, for example, the width direction (the Y direction). Each processing module stack 23 includes, for example, a heating module 24 serving as a heat treater that performs a heating treatment to remove a solvent in a resist film on the wafer W.

For example, a portion of a main transfer mechanism 3B, which serves as a substrate transfer device, is located in the transfer region 22. The main transfer mechanism 3B is movable in the width direction (the Y direction in the figure), the vertical direction, and around the vertical axis (the 0 direction) and may transfer the wafers W to each processing module in the processing block 2B. The main transfer mechanism 3B may transfer the wafers W to modules located at the same height as the processing block 2B among modules in the delivery tower T1 adjacent to the processing block 2B in the width direction (the Y direction in the figure) and a delivery tower T2 to be described below. Further, the main transfer mechanism 3B may transfer the wafers W to the delivery module TRS for the shuttle 4B provided in the processing block 2B.

Further, a partitioned flat space 5B is provided below the processing module stack 23 of the processing block 2B. The space 5B is formed from one end of the processing block 2B to the other thereof in the width direction (the Y direction). The shuttle 4B and shuttle delivery modules TRS12B and TRS12D are provided in the space 5B.

The processing blocks 2A, 2C, and 2D have the same configuration as the processing block 2B, except for differences to be described below. Each of the processing blocks 2A, 2C, and 2D includes a main transfer mechanism correspond to the main transfer mechanism 3B. Instead of the letter “B,” the same alphabetic character as that given to the processing block including the main transfer mechanism will be used as the reference numeral of the respective main transfer mechanism in the following description and the drawings. Specifically, the reference numeral “3A” will be used for the main transfer mechanism in the processing block 2A. Other main transfer mechanisms correspond to the main transfer mechanism 3B may also transfer the wafers W to the processing modules and the shuttle delivery modules TRS in the processing block in which the main transfer mechanism is provided, and the delivery towers adjacent to the processing block in the width direction (the Y direction).

Further, instead of the letter “B,” the same alphabetic character as that given to the respective processing block are used as the reference numeral of a space where the shuttle may be placed, which corresponds to the above-mentioned space 5B. Further, in a case in which the shuttle is provided in the respective processing block, the same alphabetic character as that given to the respective processing block is used as the reference numeral of the respective shuttle. Further, the same alphabet character as that given to the respective processing block in which the shuttle is provided is used as the reference numeral of the shuttle delivery module TRS. Further, the reference numeral 11 is added in front of the alphabetical characters given to the respective processing blocks with respect to the shuttle delivery modules TRS used to the same shuttle on the side of the interface block D4, and the reference numeral 12 is added in front of the alphabetical characters given to the respective processing blocks with respect to the shuttle delivery modules TRS used to the same shuttle on the side of the carrier block D1. As specific examples, according to the assignation of the reference numeral as described above, the shuttle provided in the processing block 2D is denoted by “4D,” and the delivery modules for the shuttle 4D on the side of the interface block D4 and on the side of the carrier block D1 are denoted by TRS11D and TRS12D, respectively.

The processing block 2A from the processing block 2B in that the transfer region 22 in the processing block 2A is formed to extend from the layer E1 to the layer E4 in the vertical direction.

The second stacked processing block D3 has substantially the same configuration as the first stacked processing block D2. The second stacked processing block D3 will be described below with a focus on the differences from the first stacked processing block D2.

The processing block 2D of the second stacked processing block D3 is identical to the processing block 2B in a positional relationship between the transfer region 22, the processing module stack 23, the main transfer mechanism, and the space in which the shuttles stacked in the processing modules are installed. However, developing modules that develop the wafers W with a developing solution are provided on the layers E5 to E8 of the processing block 2D, respectively. Further, the processing module stack 23 of the processing block 2D includes a heating module as a heat treater. This heating module is for PEB. Further, the processing module stack 23 of the processing block 2D includes an inspection module that captures an image of the wafer W to determine whether or not an abnormality occurs in the wafer W (that is, acquires the image of the wafer W for inspection). The space 5D for the shuttle in the processing block 2D is located at the same height as the space 5B and is in communication with the space 5B. The shuttle 4D and the shuttle delivery modules TRS11B and TRS11D are provided in the space 5D.

The processing block 2C differs from the processing block 2D in that the transfer region 22 in the processing block 2C is formed to extend from the layer E1 to the layer E4 in the vertical direction.

The delivery tower T2 is provided in an end portion of the transfer region 22 of the second stacked processing block D3 on the side of the first stacked processing block D2 (the negative side in the Y direction in FIG. 1, and the like). The delivery tower T2 is positioned such that a portion thereof overlaps the end portion of the transfer region 22 of the first stacked processing block D2 on the side of the second stacked processing block D3 (the positive side in the Y direction in FIG. 1, and the like) in a plan view. The delivery tower T2 is configured such that modules such as the delivery modules are stacked one above another in multiple stages in the vertical direction.

The interface block D4 is provided with a delivery tower T3 in its central portion in the depth direction (the X direction in FIG. 1). The delivery tower T3 is configured such that modules such as the delivery modules are stacked one above another in multiple stages in the vertical direction. Transfer mechanisms 31, 32, and 33 are provided in the front side (the negative side in the X direction) and the rear side (the positive side in the X direction) of the delivery tower T3, and the side of the exposure apparatus E (the positive side in the Y direction in FIG. 1, and the like), respectively. The transfer mechanisms 31, 32, and 33 are movable in the vertical direction and around the vertical axis (the 0 direction).

A rear-surface cleaning module 35, which supplies a cleaning liquid to a rear surface of the wafer W to clean the same, is provided on the front side (the negative side in the X direction) of the transfer mechanism 31. The rear-surface cleaning modules 35 may be stacked one above another in multiple stages in the vertical direction. A post-exposure cleaning module 36, which supplies a cleaning liquid to a front surface of the wafer W after exposure, is provided at the rear side (the positive side in the X direction) of the transfer mechanism 32. The post-exposure cleaning module 36 may be stacked one above another in multiple stages in the vertical direction. Each of the transfer mechanisms 31, 32 and 33 may transfer the wafer W to the modules in the delivery tower T3. Further, the transfer mechanism 31 may transfer the wafer W to the rear-surface cleaning module 35, the transfer mechanism 32 may transfer the wafer W to the post-exposure cleaning module 36, and the transfer mechanism 33 may transfer the wafer W to the exposure apparatus E.

The shuttles 4B and 4D and the delivery modules TRS for each shuttle will be described later. The shuttle 4B transfers the wafer W from the processing block 2D to the carrier block D1. As shown in FIG. 1, the delivery module TRS12B among the delivery modules TRS11B and TRS12B for the shuttle 4B is provided in an end portion of the space 5B on the side of the carrier block D1 (the negative side in the Y direction) to deliver the wafer W between the delivery module TRS12B and the transfer mechanism 14 of the carrier block D1. The delivery module TRS11B is provided in an end portion of the space 5D on the side of the processing block 2B (the negative side in the Y direction) in the vicinity of the interface block D4 (the positive side in the Y direction) rather than the delivery tower T2 to deliver the wafer W between the delivery module TRS11B and the main transfer mechanism 3D of the processing block 2D.

The shuttle 4D transfers the wafer W from the processing block 2B to the interface block D4. The delivery module TRS11D among the delivery modules TRS11D and TRS12D for the shuttle 4D, is provided at the end portion of the space 5D on the side of the interface block D4 (the positive side in the Y direction) to transfer the wafer W between the delivery module TRS11D and the transfer mechanism 32 of the interface block D4. The delivery module TRS12D is provided at the end portion of the space 5B on the side of the processing block 2D (the positive side in the Y direction) in the vicinity of the carrier block D1 (the negative side in the Y direction) rather than the delivery tower T2, to transfer the wafer W between the delivery module TRS12D and the main transfer mechanism 3B of the processing block 2B.

The shuttle 4A transfers the wafer W from the processing block 2C to the carrier block D1. The delivery modules TRS11A and TRS12A for the shuttle 4A are similar in arrangement position to the delivery modules TRS11B and TRS12B for the shuttle 4B.

Further, the shuttle 4C transfers the wafer W from the processing block 2A to the interface block D4. The delivery modules TRS11C and TRS12C for the shuttle 4C are similar in arrangement position to the delivery modules TRS11D and TRS12D for the shuttle 4D.

Further, the coating-developing apparatus 1 is provided with at least one controller 10. The controller 10 processes computer-executable instructions that cause the coating-developing apparatus 1 to execute various processes described in the present disclosure. The controller 10 may be configured to control each element of the coating-developing apparatus 1 to execute the various processes described herein. In one embodiment, a portion or the entirety of the controller 10 may be included in the coating-developing apparatus 1. The controller 10 may include a processor, a memory, and a communication interface. The controller 10 is implemented by, for example, a computer. The processor may be configured to read, from the memory, a program that provides logic or routines that enable various control operations, and execute the read program to perform the various control operations. This program may be stored in the memory in advance or may be acquired via a medium when needed. The acquired program is stored in the memory and is read from the memory and executed by the processor. The medium may be various computer-readable storage media H or a communication line connected to the communication interface. The storage media H may be transitory or non-transitory. The processor may be a central processing unit (CPU) or one or more circuits. The memory may include a random access memory (RAM), a read-only memory (ROM), a hard disk drive (HDD), a solid state drive (SSD), or a combination thereof. The communication interface may communicate with the coating-developing apparatus 1 via a communication line such as a local area network (LAN).

The above-described resist film forming module 21 and developing module supply a predetermined processing liquid onto the wafer W by, for example, spin coating. In the spin coating, the processing liquid is discharged onto the wafer W from a discharge nozzle, and the wafer W is rotated while being held so that the processing liquid spreads over the surface of the wafer W. In other words, the resist film forming module 21 and the developing module are rotary processing apparatuses that hold and rotate the substrate for processing.

As shown in FIG. 4, the resist film forming module 21 includes a spin chuck 201 that holds and rotates the wafer W, and a discharge nozzle (not shown) that discharges a processing liquid such as a resist liquid onto the wafer W. The resist film forming module 21 also includes a cup 202 that surrounds the wafer W held by the spin chuck 201 and collects the processing liquid scattered from the wafer W.

Further, the developing module has the same configuration as the resist film forming module, except for the processing liquid discharged from the discharge nozzle.

As shown in FIG. 5, the above-described heating module 24 includes, for example, a hot plate 401 for heating the wafer W, a plate 402 for delivering the wafer W between the hot plate 401 and the main transfer mechanisms 3A to 3D and for cooling the wafer W, a rectifying plate 403 provided above the hot plate 401, and exhaust ports 404 and 405 for exhausting interiors of the transfer region 22 and the heating module 24.

As shown in FIGS. 1, 3, and 6, the main transfer mechanism 3A includes a vertical guide 301, a horizontal guide 302, and a transfer arm 303.

The vertical guide 301 extends in the vertical direction. For example, the vertical guide 301 is provided at a position adjacent to the transfer region 22 in the depth direction (the X direction in the figure) in a plan view and between the processing module stacks 23. The vertical guide 301 is also provided so as not to interfere with the shuttle 4A and the wafer W transferred by the shuttle 4A.

The horizontal guide 302 extends in the width direction (the Y direction in the figure) and moves along the vertical guide 301. For example, the horizontal guide 302 is provided at a rear end portion of the transfer region 22 (the positive side in the X direction in the figure).

The transfer arm 303 supports and moves the wafer W. Specifically, the transfer arm 303 moves the wafer W in the horizontal direction (the X and Y directions in the figure) and around the vertical axis (the 0 direction) while holding the wafer W.

The transfer arm 303 includes a movable body 311 that moves along the horizontal guide 302, and a base 312 that rotates relative to the movable body 311. The transfer arm 303 also includes a fork 313. The fork 313 is an example of a substrate support that is configured to be movable and support the substrate. The fork 313 moves toward or away from the base 312. A plurality of forks 313 may be provided in one transfer arm 303.

Further, the main transfer mechanisms 3B, 3C, and 3D have the same configuration as the main transfer mechanism 3A.

### <Wafer Processing>

Next, examples of a wafer processing using the coating-developing apparatus 1 and a transfer path will be described.

For example, first, by the transfer mechanism 14, the wafer W is taken out of the carrier C loaded into the carrier block D1 of the coating-developing apparatus 1 and placed on the placement plate 12, and is transferred to the delivery module of the delivery tower T1.

Subsequently, the wafer W is transferred by the transfer mechanism 16 to the hydrophobization treatment module 15 where the wafer W is subjected to the hydrophobization treatment. Thereafter, the wafer W is returned to the delivery tower T1 by the transfer mechanism 16.

Subsequently, the wafer W is transferred by the main transfer mechanism 3A or 3B to the resist film forming module 21 where the resist film is formed on the wafer W.

Specifically, first, the operation of the transfer arm 303 of the main transfer mechanism 3A or 3B is controlled by the controller 10 such that the wafer W is transferred to the resist film forming module 21.

More specifically, the fork 313 supporting the wafer W is moved from a standby position on its base end to a delivery position on the spin chuck 201 of the resist film forming module 21. The delivery position is adjusted in advance using a method to be described below. Hereinafter, for the sake of simplification in description, it is assumed that the position of the wafer W on the fork 313, that is, a positional relationship between the fork 313 and the wafer W supported by the fork 313, remains the same each time.

After the fork 313 is moved to the delivery position adjusted in advance, lift pins (not shown) in the resist film forming module 21 are raised, and the wafer W is delivered onto the lift pins. Subsequently, the fork 313 is returned to the standby position, and the lift pins are lowered so that the wafer W is delivered onto and held by the spin chuck 201 of the resist film forming module 21.

Subsequently, the resist liquid is discharged from the discharge nozzle onto the wafer W being rotated by the spin chuck 201, so that the resist film is formed on the wafer W.

After the resist film is formed, an EBR (Edge Bead Removal) process is performed in the same resist film forming module 21.

Specifically, a removal liquid such as a solvent is discharged from the discharge nozzle onto the wafer W being rotated by the spin chuck 201, and the resist film on a peripheral edge portion of the wafer W is removed in an annular shape centered at the wafer W.

Thereafter, the wafer W is transferred by the main transfer mechanism 3A or 3B to the heating module 24 in the first stacked processing block where the wafer W is subjected to a pre-baking process. Next, the wafer W is transferred by the main transfer mechanism 3A or 3B to the delivery module of the delivery tower T2, and then is transferred by the main transfer mechanism 3C or 3D to the delivery module of the delivery tower T3 of the interface block D4. Further, the wafer W, on which the resist film has been formed, may be transferred from the processing block 2A to the delivery tower T3 via the main transfer mechanism 3A, the shuttle 4C, the delivery modules TRS12C and TRS11C, and the transfer mechanism 32 while bypassing the second stacked processing block D3. Further, the wafer W, on which the resist film has been formed, may be transferred from the processing block 2B to the delivery tower T3 via the main transfer mechanism 3B, the shuttle 4D, the delivery modules TRS12D and TRS11D, and the transfer mechanism 32 while bypassing the second stacked processing block D3.

Subsequently, the wafer W is transferred by the transfer mechanism 31 to the rear-surface cleaning module 35 where the rear surface of the wafer W is cleaned. Thereafter, the wafer W is returned to the delivery tower T3 by the transfer mechanism 31, and is transferred by the transfer mechanism 33 to the exposure apparatus E where the wafer W is subjected to an exposure process. Subsequently, the exposed wafer W is returned to the delivery tower T3 by the transfer mechanism 33, and is transferred by the transfer mechanism 32 to the post-exposure cleaning module 36 where the exposed wafer W is cleaned.

The wafer W, which has been cleaned by the post-exposure cleaning module 36, is first returned to the delivery tower T3 by, for example, the transfer mechanism 32. Thereafter, the wafer W is transferred by the main transfer mechanism 3C or 3D in the order of the heating module→the developing module→the inspection module inside the second stacked processing block D3. A resist pattern is formed on the wafer W which has been subjected to the PEB (Post Exposure Bake) process, and subsequently, whether or not an abnormality occurs in the wafer W is determined. Thereafter, the wafer W is returned to the delivery tower T2 by the main transfer mechanism 3C or 3D, and subsequently is returned to the delivery tower T1 by the main transfer mechanism 3A or 3B. Further, the wafer W, which has been processed by the inspection module, may be returned from the processing block 2C to the delivery tower T1 via the main transfer mechanism 3C, the shuttle 4A, the delivery modules TRS11A and TRS12A, and the transfer mechanism 16 while bypassing the first stacked processing block D2. Further, the wafer W, which has been processed by the inspection module, may be returned from the processing block 2D to the delivery tower T1 via the main transfer mechanism 3D, the shuttle 4B, the delivery modules TRS11B and TRS12B, and the transfer mechanism 16 while bypassing the first stacked processing block D2.

Then, the wafer W is returned from the delivery tower T1 to the carrier C by the transfer mechanism 14. In this way, a series of wafer processing is terminated.

### First Embodiment

### <Controller 10>

FIG. 7 is a functional block diagram of the controller 10 according to a first embodiment, which illustrates the transfer of the wafer W to the resist film forming module 21 which is the rotary processing apparatus.

As shown in FIG. 7, the controller 10 according to this embodiment includes a temperature acquisitor 510, a position acquisitor 511, a delivery position adjustor 512, and an operation controller 513, which are implemented by reading and executing the program stored in the memory by the aforementioned processor. Of these, the position acquisitor 511 and the delivery position adjustor 512 are used to adjust the delivery position. The adjustment of the delivery position is performed for each resist film forming module 21 and each transfer arm 303. Hereinafter, only the adjustment of the delivery position relating to one resist film forming module 21 by the transfer arm 303 of the main transfer mechanism 3A will be described.

The temperature acquisitor 510 acquires maximum and minimum temperatures which may be set as processing temperatures of the heating module 24. Specifically, the temperature acquisitor 510 acquires the maximum and minimum temperatures which may be set for the hot plate 401 of the heating module 24. This acquisition is performed, for example, for each heating module 24. In this case, the maximum and minimum temperatures may differ for each heating module 24.

Further, the maximum and minimum temperatures are input by an operator with an input device such as a touch panel or keyboard provided in the controller 10 when starting up the coating-developing apparatus 1, and are stored in the memory. For example, the temperature acquisitor 510 acquires the maximum and minimum temperatures stored in the memory.

Further, the maximum temperature may be the highest temperature among settable temperatures, excluding temperatures with a relatively low setting frequency.

Similarly, the minimum temperature may be the lowest temperature among the settable temperatures, excluding temperatures with a relatively low setting frequency.

The position acquisitor 511 acquires an eccentric position of the wafer W held by the resist film forming module 21 with respect to a rotational center of the resist film forming module 21 based on the maximum and minimum temperatures acquired by the temperature acquisitor 510.

Specifically, the position acquisitor 511 acquires the eccentric position of the center of the wafer W held by the spin chuck 201 of the resist film forming module 21 with respect to a rotational center of the spin chuck 201 based on the maximum and minimum temperatures acquired by the temperature acquisitor 510. Hereinafter, the term “eccentric position” refers to the eccentric position of the center of the wafer W held by the spin chuck 201 of the resist film forming module 21 with respect to the rotational center of the spin chuck 201.

More specifically, the position acquisitor 511 first acquires an eccentric position P_{MAX} corresponding to the maximum temperature and an eccentric position P_{Min} corresponding to the minimum temperature.

The eccentric position P_{MAX} corresponding to the maximum temperature is an eccentric position available when the heating module 24 is actually set to have the maximum temperature. Specifically, the eccentric position P_{MAX} is the eccentric position available when each of the heating modules 24 is actually set to have the maximum temperature of a respective heating module 24. A more specific example is as follows. That is, in a state in which the hot plate 401 of each of the heating modules 24 is set to have the maximum temperature of a respective heating module 24, the fork 313 of the transfer arm 303 is moved to a pre-adjustment delivery position P0 with respect to the resist film forming module 21 as a set target to deliver the wafer W. Then, the EBR process is performed on the wafer W in the resist film forming module 21 as the set target, and an eccentric position obtained from a result of the EBR process is set to the eccentric position P_{MAX} corresponding to the maximum temperature.

The eccentric position (specifically, X-direction and Y-direction coordinates) may be calculated from the result of the EBR process in, for example, the following manner. The “X-direction coordinate” and “Y-direction coordinate” refer to an X-direction coordinate and a Y-direction coordinate in the transfer by the transfer arm 303, respectively.

First, a removal width of the resist film by the EBR process is obtained for the following four points:
Two points with different X-direction coordinates and the same Y-direction coordinates
Two points with different Y-direction coordinates and the same X-direction coordinates

A difference in the removal width between the former two points is calculated as the X-direction coordinate of the eccentric position, and a difference in the removal width between the latter two points is calculated as the Y-direction coordinate of the eccentric position.

In this way, the eccentric position may be calculated from the result of the EBR process.

The removal width of the resist film by the EBR process may be calculated from a capturing result (that is, the image) of the wafer W captured by the inspection module provided in the processing module stack 23.

Further, the removal width of the resist film by the EBR process may be measured outside the coating-developing apparatus 1.

The calculation of the eccentric position from the removal width of the resist film by the EBR process may be performed in the position acquisitor 511. Further, the calculation of the eccentric position from the removal width of the resist film by the EBR process may be performed outside the coating-developing apparatus 1. The calculated eccentric position may be input by an operator with an input device such as a touch panel provided in the controller 10, and may be acquired by the controller 10 (the position acquisitor 511 in this embodiment).

On the other hand, the eccentric position P_{Min} corresponding to the minimum temperature is an eccentric position available when the heating module 24 is actually set to have the minimum temperature. Specifically, the eccentric position P_{Min} is the eccentric position available when each of the heating modules 24 is actually set to have the minimum temperature of the respective heating module 24. More Specifically, in a state in which the hot plate 401 of each of the heating modules 24 is set to have the maximum temperature of the respective heating module 24, the fork 313 of the transfer arm 303 is moved to the pre-adjustment delivery position P0 with respect to the resist film forming module 21 as the set target to deliver the wafer W. Then, the EBR process is performed on the wafer W in the resist film forming module 21 as the set target, and an eccentric position obtained from a result of the EBR process is set to the eccentric position P_{Min} corresponding to the minimum temperature.

Based on the eccentric position P_{MAX} corresponding to the maximum temperature and the eccentric position P_{Min} corresponding to the minimum temperature, the position acquisitor 511 acquires an adjustment eccentric position P_{Cal}.

The adjustment eccentric position P_{Cal} is, for example, a center of the eccentric position P_{MAX} corresponding to the maximum temperature and the eccentric position P_{Min} corresponding to the minimum temperature. That is, the adjustment eccentric position P_{Cal} is represented by Equation below:

$${P}_{Cal} = ( {P}_{MAX} + {P}_{Min} ) / 2$$

The delivery position adjustor 512 adjusts the delivery position based on the adjustment eccentric position P_{Cal}. Specifically, based on the adjustment eccentric position P_{Cal}, the delivery position adjustor 512 calculates a post-adjustment delivery position Pₚ so as to eliminate eccentricity at the pre-adjustment delivery position P₀ which is a predetermined temporary delivery position when the coating-developing apparatus 1 is started up. The post-adjustment delivery position Pp is calculated by, for example, Equation below.

$${P}_{p} = {P}_{0} - {P}_{Cal}$$

The operation controller 513 controls the operation of the transfer arm 303. For example, after the calculation of the post-adjustment delivery position Pₚ, the operation controller 513 controls the operation of the transfer arm 303 to move the fork 313 from the above-mentioned standby position to the post-adjustment delivery position Pₚ.

Using the temperature acquisitor 510, the position acquisitor 511, the delivery position adjustor 512, and the operation controller 513, the controller 10 acquires the eccentric position based on the maximum and minimum temperatures which may be set as the processing temperatures of the heating module 24, and adjusts the position of the transfer arm 303 when transferring the wafer W to the resist film forming module 21 based on the eccentric position. Specifically, the controller 10 acquires the adjustment eccentric position P_{Cal} based on the eccentric position P_{MAX} corresponding to the maximum temperature and the eccentric position P_{Min} corresponding to the minimum temperature, and adjusts the position of the transfer arm 303 when transferring the wafer W to the resist film forming module 21 based on the adjustment eccentric position P_{Cal}.

### <Flow of Adjusting Delivery Position>

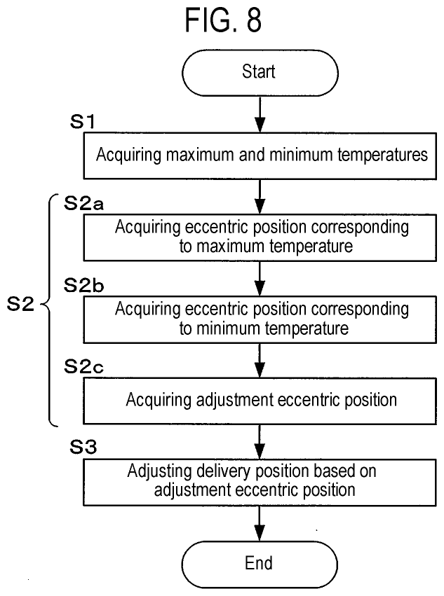

FIG. 8 is a flowchart illustrating an example of a flow of adjusting the delivery position according to the first embodiment. The adjustment of the delivery position is performed when, for example, the coating-developing apparatus 1 is started up.

As shown in FIG. 8, first, the temperature acquisitor 510 acquires the maximum and minimum temperatures which may be set as the processing temperatures of the heating module 24 (Step S1).

Specifically, first, the temperature acquisitor 510 acquires, for each heating module 24, the above-mentioned maximum and minimum temperatures that were previously input by the operator with the input device of the controller 10 and stored in the memory.

Next, the position acquisitor 511 acquires the eccentric position based on the maximum and minimum temperatures acquired in Step S1 (Step S2).

The eccentric position acquired in Step S2 is an eccentric position when the wafer W is delivered from the transfer arm 303 to the resist film forming module 21 at the pre-adjustment delivery position P0.

Step S2 includes Steps S2a to S2c as follows.

In Step S2a, the position acquisitor 511 acquires the eccentric position P_{MAX} corresponding to the maximum temperature.

Specifically, first, the controller 10 sets the hot plate 401 of each of the heating modules 24 to have the maximum temperature of the respective heating module 24.

Then, the controller 10 moves the fork 313 of the transfer arm 303 supporting the wafer W to the pre-adjustment delivery position P₀ with respect to the target resist film forming module 21 and deliver the wafer W. Next, the controller 10 causes the resist film forming module 21 as the setting target to perform the resist film forming process and the EBR process.

Next, the position acquisitor 511 acquires the eccentric position of the wafer W after the EBR process.

Specifically, the controller 10 causes the wafer W after the EBR process, to be transferred to the inspection module provided in one of the processing module stacks 23, and causes the inspection module to capture an image of the wafer W. From the image of the wafer W after the EBR process thus obtained, the position acquisitor 511 acquires the removal width of the wafer W by the EBR process when the hot plate 401 of each of the heating modules 24 is set to have the maximum temperature of the respective heating module 24. Then, the position acquisitor 511 calculates the eccentric position during the EBR process based on the acquired removal width.

Alternatively, the operator may move the wafer W after the EBR process to a measuring device provided in the outside of the coating-developing apparatus 1, and the measuring device may acquire the removal width of the wafer W during the EBR process when the hot plate 401 of each of the heating modules 24 is set to have the maximum temperature of the respective heating module 24. Then, the above-mentioned removal width input by the operator with the input device of the controller 10 may be acquired, and the position acquisitor 511 may calculate the eccentric position during the EBR process based on the acquired removal width. Further, the eccentric position during the EBR process based on the removal width of the wafer W may be calculated outside the coating-developing apparatus 1. Such a calculation result may be input by the operator with the input device of the controller 10 and may be acquired by the position acquisitor 511.

The eccentric position during the EBR process acquired in this manner becomes the eccentric position P_{MAX} corresponding to the maximum temperature. Further, in the case in which the hot plate 401 of each of the heating modules 24 is set to have the maximum temperature of the respective heating module 24, the above-described operations may be repeated for a plurality of wafers W, and the position acquisitor 511 may acquire, as the eccentric position P_{MAX} corresponding to the maximum temperature, a representative position (for example, an average value) of eccentric positions of the plurality of wafers W during the EBR process.

In Step S2b, the position acquisitor 511 acquires the eccentric position P_{Min} corresponding to the minimum temperature.

Specifically, first, the controller 10 causes the hot plate 401 of each of the heating modules 24 to have the minimum temperature of the respective heating module 24.

Thereafter, the controller 10 moves the fork 313 of the transfer arm 303 supporting the wafer W to the pre-adjustment delivery position P0 with respect to the resist film forming module 21 as a setting target, to deliver the wafer W. Next, the controller 10 causes the resist film forming module 21 as a setting target to perform the resist film forming process and the EBR process.

Next, the position acquisitor 511 acquires the eccentric position of the wafer W after the EBR process.

Specifically, the controller 10 causes the wafer W after the EBR process to be transferred to the inspection module provided in one of the processing module stacks 23, and causes the inspection module to capture an image of the wafer W. From the image of the wafer W after the EBR process thus acquired, the position acquisitor 511 acquires a removal width of the wafer W by the EBR process when the hot plate 401 of each of the heating modules 24 is set to have the maximum temperature. Then, the position acquisitor 511 calculates the eccentric position during the EBR process based on the acquired removal width.

Alternatively, as in Step S2a, the acquisition of the removal width of the wafer W by the EBR process when the hot plate 401 of each of the heating modules 24 is set to have its minimum temperature and the calculation of the eccentric position during the EBR process may be performed outside the coating-developing apparatus 1, and may be input by the operator with the input device of the controller 10.

The eccentric position during the EBR process acquired in this manner becomes the eccentric position P_{Min} corresponding to the minimum temperature. Further, in the state in which the hot plate 401 of each of the heating modules 24 is set to have the maximum temperature of the respective heating module 24, the above-described operations may be repeated for a plurality of wafers W, and the position acquisitor 511 may acquire, as the eccentric position P_{Min} corresponding to the minimum temperature, a representative position (for example, an average value) of eccentric positions of the plurality of wafers W during the EBR process.

Further, Step S2b may be performed before Step S2a.

In Step S2c, the position acquisitor 511 acquires the adjustment eccentric position P_{Cal} based on the eccentric position P_{MAX} corresponding to the maximum temperature and the eccentric position P_{Min} corresponding to the minimum temperature acquired in Steps S2a and S2b, respectively. Specifically, the position acquisitor 511 acquires the adjustment eccentric position P_{Cal} according to Equation below.

$${P}_{Cal} = ( {P}_{MAX} + {P}_{Min} ) / 2$$

After Step S2, the delivery position adjustor 512 adjusts the delivery position based on the adjustment eccentric position P_{Cal} (Step S3).

Specifically, the delivery position adjustor 512 calculates the post-adjustment delivery position Pₚ from the pre-adjustment delivery position P₀ and the adjustment eccentric position P_{Cal} according to Equation below.

$${P}_{p} = {P}_{0} - {P}_{Cal}$$

In this way, the flow of adjusting the delivery position is terminated.

The post-adjustment delivery position is used as the delivery position during an actual processing after such an adjustment, that is, during mass production.

### <Major Operative Effects of the Present Embodiment>

When the delivery position is adjusted in an embodiment different from this embodiment (hereinafter, referred to as a comparative embodiment), the wafer W on the fork 313 moved to the post-adjustment delivery position may be significantly decentered with respect to the spin chuck during the mass production after the adjustment.

In the comparative embodiment, the eccentric position P_{Min} corresponding to the minimum temperature which may be set as the processing temperature of the heating module 24 is used as the adjustment eccentric position, and the delivery position is adjusted based on the adjustment eccentric position. In the comparative embodiment, during the mass production after the adjustment of the delivery position, when the temperature of each of the heating modules 24 (specifically, the hot plates 401) is set to the maximum temperatures which may be set as a temperature of the respective heating module 24, the wafer W on the fork 313 of the main transfer mechanism 3A moved to the post-adjustment delivery position will be significantly decentered with respect to the spin chuck. The reason for this is as follows.

For example, a length of the vertical guide 301 of the main transfer mechanism 3A changes due to the influence of heat from the heating modules 24 (specifically, the hot plates 401). As a result, as indicated by an imaginary line in FIG. 6, the vertical guide 301 is deformed to be bent. This displaces the position of the fork 313. As a result, the eccentric position P_{MAX} corresponding to the maximum temperature and the eccentric position P_{Min} corresponding to the minimum temperature are significantly spaced apart from each other. Therefore, in the comparative embodiment in which the delivery position is adjusted using the eccentric position P_{Min} corresponding to the minimum temperature as the adjustment eccentric position, when the temperature of each of the heating modules 24 (specifically, the hot plates 401) is set to the maximum temperature during the mass production after the adjustment of the delivery position, the wafer W on the fork 313 of the main transfer mechanism 3A moved to the post-adjustment delivery position may be significantly decentered with respect to the spin chuck.

In contrast, in this embodiment, the adjustment eccentric position P_{Cal} is acquired based on the eccentric position P_{MAX} corresponding to the maximum temperature and the eccentric position P_{Min} corresponding to the minimum temperature, and the delivery position is adjusted based on the adjustment eccentric position P_{Cal}. The adjustment eccentric position P_{Cal} is relatively close to both the eccentric position P_{MAX} corresponding to the maximum temperature and the eccentric position P_{Min} corresponding to the minimum temperature. Therefore, according to this embodiment, even if the temperatures of all of the heating modules 24 (specifically, the hot plates 401) are set to the maximum or minimum temperatures during the mass production after the adjustment of the delivery position, a degree of eccentricity of the wafer W on the fork 313 of the main transfer mechanism 3A, which is moved to the post-adjustment delivery position, with respect to the spin chuck 201, may be suppressed within a relatively narrow range. In other words, according to this embodiment, the wafer W may be transferred to a target position with high accuracy relative to the spin chuck 201, regardless of the temperatures of the heating modules 24.

### Second Embodiment

### <Controller 10>

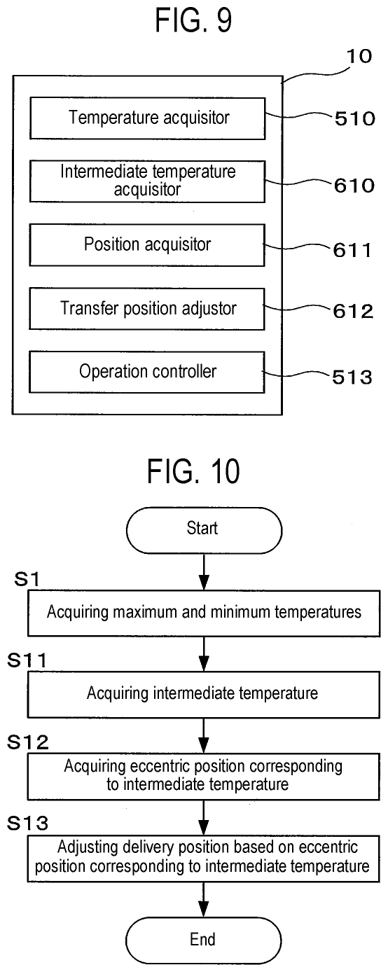

FIG. 9 is a functional block diagram of the controller 10 according to a second embodiment, which illustrates the transfer of the wafer W to the resist film forming module 21.

As shown in FIG. 9, the controller 10 according to this embodiment includes a temperature acquisitor 510, an intermediate temperature acquisitor 610, a position acquisitor 611, a delivery position adjustor 612, and an operation controller 513, which are implemented by reading and executing the program stored in the memory by the aforementioned processor. Of these, the intermediate temperature acquisitor 610, the position acquisitor 611, and the delivery position adjustor 612 are used to adjust the delivery position.

As in the first embodiment, the temperature acquisitor 510 acquires the maximum and minimum temperatures which may be set as processing temperatures of the heating module 24.

The intermediate temperature acquisitor 610 acquires an intermediate temperature between the maximum and minimum temperatures acquired by the temperature acquisitor 510. Specifically, the intermediate temperature acquisitor 610 calculates an average value of the maximum and minimum temperatures and acquires the same as the intermediate temperature.

The position acquisitor 611 acquires an eccentric position P_{Mid} corresponding to the intermediate temperature.

The eccentric position P_{Mid} corresponding to the intermediate temperature is an eccentric position available when the heating module 24 is actually set to have the intermediate temperature. Specifically, the eccentric position P_{Mid} is the eccentric position available when each of the heating modules 24 is actually set to have the intermediate temperature of the respective heating module 24. A more specific example is as follows. In a state in which the hot plate 401 of each of the heating modules 24 is set to have the intermediate temperature of the respective heating module 24, the fork 313 of the transfer arm 303 is moved to the pre-adjustment delivery position P₀ with respect to the resist film forming module 21 as a setting target, to deliver the wafer W. Then, the EBR process is performed in the resist film forming module 21 as a setting target, and the eccentric position based on a result of the EBR process is the eccentric position P_{Mid} corresponding to the intermediate temperature.

The delivery position adjustor 612 adjusts the delivery position based on the eccentric position P_{Mid} corresponding to the intermediate temperature. Specifically, the delivery position adjustor 512 calculates the post-adjustment delivery position Pₚ based on the eccentric position P_{Mid} corresponding to the intermediate temperature so as to eliminate eccentricity from the pre-adjustment delivery position P0. The post-adjustment delivery position Pp is calculated by, for example, Equation below.

$${P}_{p} = {P}_{0} - {P}_{Mid}$$

As in the first embodiment, the operation controller 513 controls the operation of the transfer arm 303.

Using the temperature acquisitor 510, the intermediate temperature acquisitor 610, the position acquisitor 611, the delivery position adjustor 612, and the operation controller 513, the controller 10 acquires the eccentric position based on the maximum and minimum temperatures which may be set as processing temperatures of the heating modules 24, and adjusts the position of the transfer arm 303 when delivering the wafer W to the resist film forming module 21 based on the eccentric position. Specifically, the controller 10 acquires the intermediate temperature between the maximum and minimum temperatures, acquires the eccentric position P_{Mid} corresponding to the intermediate temperature, and adjusts the position of the transfer arm 303 when delivering the wafer W to the resist film forming module 21 based on the eccentric position P_{Mid} corresponding to the intermediate temperature.

### <Flow of Adjusting Delivery Position>

FIG. 10 is a flowchart illustrating an example of a flow of delivering the delivery position according to the second embodiment.

As shown in FIG. 10, in Step S1, the temperature acquisitor 510 acquires the maximum and minimum temperatures which may be set as processing temperatures of the heating modules 24. Then, the intermediate temperature acquisitor 610 acquires the intermediate temperature between the maximum and minimum temperatures (Step S11).

Specifically, the intermediate temperature acquisitor 610 calculates an average value of the maximum and minimum temperatures acquired in Step S1 and acquires the same as the intermediate temperature.

Next, the position acquisitor 611 acquires the eccentric position P_{Mid} corresponding to the intermediate temperature (Step S12).

Specifically, first, the controller 10 causes the hot plate 401 of each of the heating modules 24 to have the intermediate temperature of the respective heating module 24.

Then, the controller 10 moves the fork 313 of the transfer arm 303 supporting the wafer W to the pre-adjustment delivery position P₀ with respect to the resist film forming module 21 as a setting target, to deliver the wafer W. Next, the controller 10 causes the resist film forming module 21 as a setting target to perform the resist film forming process and the EBR process.

Next, the position acquisitor 611 acquires the eccentric position of the wafer W after the EBR process.

Specifically, the controller 10 causes the wafer W after the EBR process to be transferred to the inspection module provided in one of the processing module stacks 23, and causes the inspection module to capture an image of the wafer W. From the image of the wafer W after the EBR process thus acquired, the position acquisitor 611 acquires a removal width of the wafer W by the EBR process when the hot plate 401 of each of the heating modules 24 is set to have the intermediate temperature of the respective heating module 24. Then, the position acquisitor 511 calculates the eccentric position during the EBR process based on the acquired removal width.

Alternatively, as in Step S2a, the acquisition of the removal width of the wafer W by the EBR process when the hot plate 401 of each of the heating modules 24 is set to have the intermediate temperature of the respective heating module 24, and the calculation of the eccentric position during the EBR process may be performed outside the coating-developing apparatus 1, and may be input by the operator with the input device of the controller 10.

The eccentric position during the EBR process acquired in this manner becomes the eccentric position P_{Mid} corresponding to the intermediate temperature. Further, the above-described operations may be repeated for a plurality of wafers W in the state in which the hot plate 401 of each of the heating modules 24 is set to have the intermediate temperature of the respective heating module 24, and the position acquisitor 611 may acquire, as the eccentric position P_{Mid} corresponding to the intermediate temperature, a representative position (for example, an average value) of the eccentric positions of the plurality of wafers W during the EBR process.

Then, the delivery position adjustor 612 adjusts the delivery position based on the eccentric position P_{Mid} corresponding to the intermediate temperature (Step S13).

Specifically, the delivery position adjustor 612 calculates the post-adjustment delivery position Pₚ from the pre-adjustment delivery position P₀ and the eccentric position P_{Mid} corresponding to the intermediate temperature according to Equation below.

$${P}_{p} = {P}_{0} - {\underline{P}}_{Mid}$$

In the way, the flow of adjusting the delivery position is terminated.

The post-adjustment delivery position is used as the delivery position during actual processing after the adjustment, that is, during the mass production.

### <Major Operative Effects of the Present Embodiment>

In the aforementioned comparative embodiment, the eccentric position P_{Min} corresponding to the settable minimum temperature is used as the adjustment eccentric position PCal, and the delivery position is adjusted based on the adjustment eccentric position. That is, the temperature of the heating module 24 (specifically, the hot plate 401) during the adjustment of the delivery position is set to the minimum temperature. In this comparative embodiment, the temperature of the heating module 24 (specifically, the hot plate 401) may significantly vary between the adjustment of the delivery position and the mass production after the adjustment of the delivery position. When the temperature of the heating module 24 (specifically, the hot plate 401) varies significantly, the deformation of the vertical guide 301 of the main transfer mechanism 3A may also vary significantly. As a result, in the comparative embodiment, during the mass production after the adjustment of the delivery position, the wafer W on the fork 313 moved to the post-adjustment delivery position may be decentered significantly with respect to the spin chuck.

In contrast, in this embodiment, the temperature of the heating module 24 (specifically, the hot plate 401) during the adjustment of the delivery position is set to the intermediate temperature between the settable maximum and minimum temperatures. This makes it possible to reduce a difference in temperature of the heating module 24 (specifically, the hot plate 401) between the adjustment of the delivery position and the mass production after the adjustment of the delivery position. Therefore, according to this embodiment, even if the temperatures of all of the heating modules 24 (specifically, the hot plates 401) are set to their respective maximum or minimum temperatures during the mass production after the adjustment of the delivery position, the degree of eccentricity of the wafer W on the fork 313 of the main transfer mechanism 3A, which is moved to the post-adjustment delivery position, with respect to the spin chuck 201, may be suppressed within a relatively narrow range. In other words, even in this embodiment, the wafer W may be transferred to the target position on the spin chuck 201 with high accuracy, regardless of the temperature of the heating module 24.

### <Modification of Coating-Developing Apparatus>

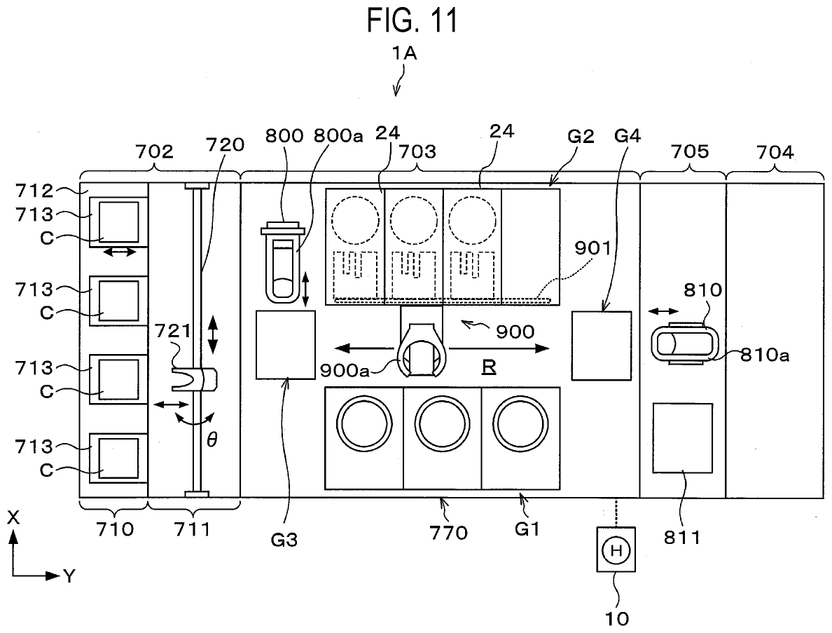

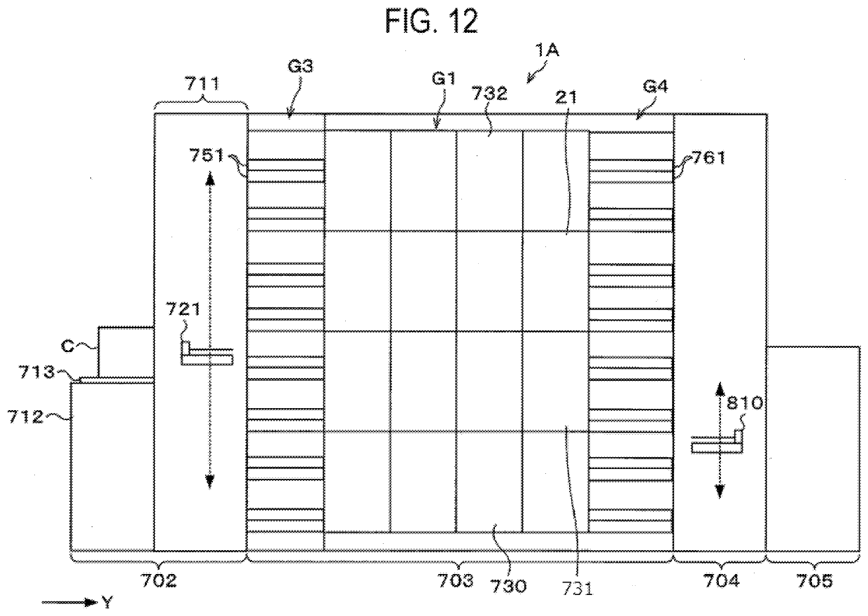

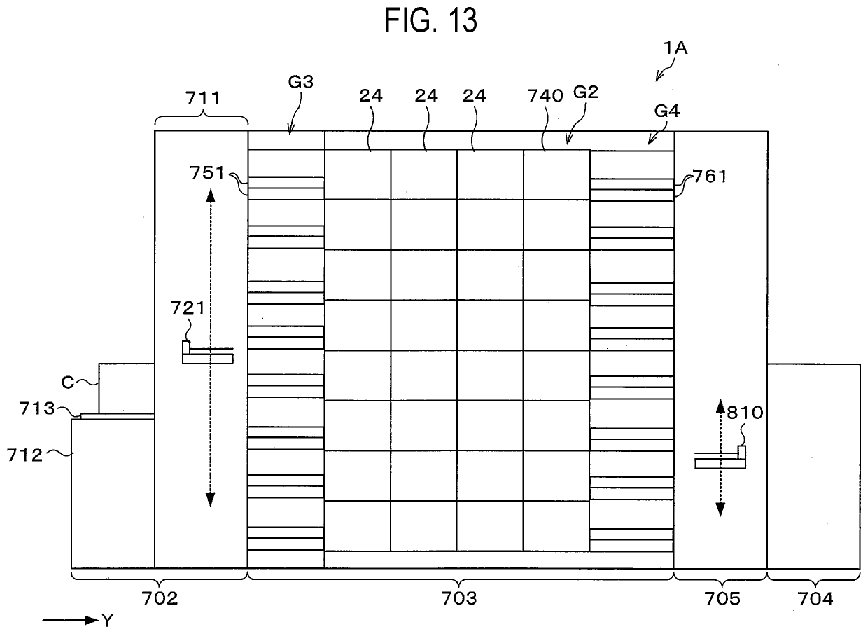

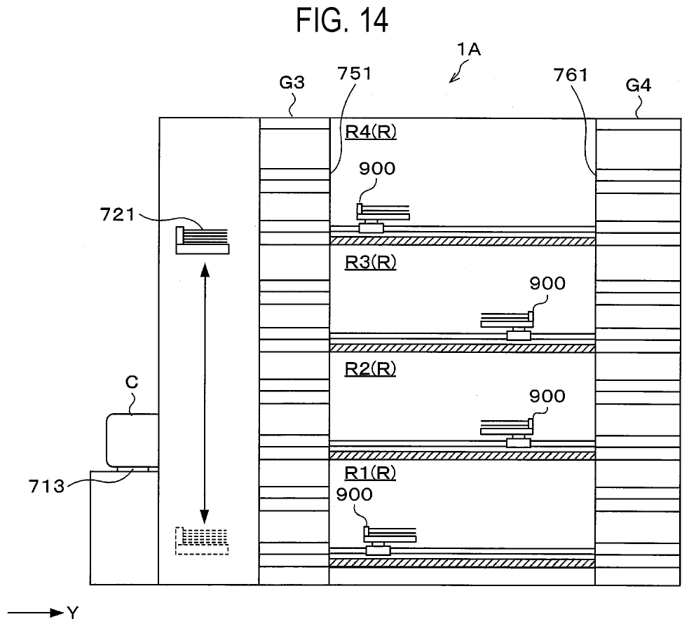

FIG. 11 is a plan view showing a schematic configuration of Modification of the coating-developing apparatus including the substrate transfer device according to the present embodiment. FIGS. 12 and 13 are views showing schematic internal configurations on front and rear sides of the coating-developing apparatus, respectively. FIG. 14 is a longitudinal side view showing a schematic internal configuration of the coating-developing apparatus.

As shown in FIGS. 11 to 13, a coating-developing apparatus 1A includes a carrier station 702 through which the carriers C are loaded into and unloaded from the outside, and a processing station 703 provided with various processing modules for performing predetermined processes such as the resist film formation process. The coating-developing apparatus 1A also includes an interface station 705 located to be adjacent to the processing station 703 on the positive side in the Y direction (the right side in FIG. 11) and for transferring the wafers W between the processing station 703 and an exposure apparatus 704. The carrier station 702, the processing station 703, and the interface station 705 are integrally connected to each other.

The carrier station 702 is divided into, for example, a carrier loading/unloading part 710 and a wafer transfer part 711. For example, the carrier loading/unloading part 710 is located at an end portion of the coating-developing apparatus 1A on the negative side in the Y direction (the left side in FIG. 11). A carrier stage 712 is provided in the carrier loading/unloading part 710. A plurality of (for example, four) placement plates 713 are provided on the carrier stage 712. The placement plates 713 are aligned in a line in the X direction as the horizontal direction (the vertical direction in FIG. 11). The carriers C may be placed on the placement plates 713 when they are loaded into and unloaded from the coating-developing apparatus 1A.

The wafer transfer part 711 is provided with a transfer device 721 that may move on a transfer path 720 extending in the X direction (the vertical direction in FIG. 11). The transfer device 721 is also movable in the vertical direction and around the vertical axis (the 0 direction), and may transfer the wafers W between the carrier C on each placement plate 713 and a delivery module in a third block G3 of the processing station 703, which will be described later.

The processing station 703 is provided with a plurality of, for example, first to fourth blocks G1, G2, G3, and G4, each of which including various modules. For example, the first block G1 is provided on a front side of the processing station 703 (the negative side in the X direction in FIG. 11), and the second block G2 is provided at a rear side of the processing station 703 (the positive side in the X direction in FIG. 11). The third block G3 is provided on the side of the carrier station 702 of the processing station 703 (the negative side in the Y direction in FIG. 11), and the fourth block G4 is provided on the side of the interface station 705 of the processing station 703 (the positive side in the Y direction in FIG. 11).

As shown in FIG. 12, the first block G1 includes a plurality of liquid processing modules, such as a developing module 730, a lower anti-reflective film forming module 731 that forms an anti-reflective film on an underlying layer of the resist film on the wafer W (hereinafter, referred to as a “lower anti-reflective film”), a resist film forming module 21, and an upper anti-reflective film forming module 732 that forms an anti-reflective film on a layer above the resist film on the wafer W (hereinafter, referred to as an “upper anti-reflective film”), which are provided sequentially from the bottom.

For example, four developing modules 730, four lower anti-reflective film forming modules 731, four resist film forming modules 21, and four upper anti-reflective film forming modules 732 are arranged side by side in the horizontal direction. The number and arrangement of the developing modules 730, the lower anti-reflective film forming modules 731, the resist film forming modules 21, and the upper anti-reflective film forming modules 732 may be arbitrarily selected.

For example, in the second block G2, as shown in FIG. 13, heating modules 24 and adhesion modules 740 for improving the adhesion of the resist liquid to the wafer W are arranged side by side in the vertical direction, and the like The number and arrangement of these heating modules 24 and adhesion modules 740 may also be arbitrarily selected.

For example, the third block G3 includes a plurality of delivery modules 751 arranged sequentially from the bottom. Further, the fourth block G4 includes a plurality of delivery modules 761 arranged sequentially from the bottom.

As shown in FIG. 11, a wafer transfer region R is formed in a region surrounded by the first block G1 to the fourth block G4.

Further, a wafer transfer module 800 is provided to be adjacent to the third block G3 on the positive side in the X direction. The wafer transfer module 800 includes a transfer arm 800a that is movable, for example, in the X direction, the 0 direction, and the vertical direction. The wafer transfer module 800 moves vertically while supporting the wafer W with the transfer arm 800a, and may transfer the wafer W to each delivery module in the third block G3.

The interface station 705 is provided with a wafer transfer module 810 and a delivery module 811. The wafer transfer module 810 includes a transfer arm 810a that is movable, for example, in the Y direction, the 0 direction, and the vertical direction. The wafer transfer module 810 supports the wafer W by, for example, the transfer arm 810a, and may transfer the wafer W between each delivery module in the fourth block G4, the delivery module 811, and the exposure apparatus 704.

The wafer transfer region R will be further described. As shown in FIG. 14, the wafer transfer region R is constituted with four transfer regions R1 to R4 stacked sequentially from the bottom. Each of the transfer regions R1 to R4 is formed to extend in a direction from the third block G3 toward the fourth block G4 (the Y direction in the figure). A liquid processing module such as the resist film forming module 21 is arranged on one sides of the transfer regions R1 to R4 in the width direction (the X direction in the figure), and, for example, the heating module 24 is arranged on the other sides thereof.

Further, a transfer arm 900a of a transfer mechanism 900, which serves as the substrate transfer device according to the present disclosure, is located in each of the transfer regions R1 to R4. The transfer mechanism 900 transfers the wafer W to a module (such as the resist film forming module 21) adjacent to the transfer region in which the transfer mechanism 900 is located, among the transfer regions R1 to R4.

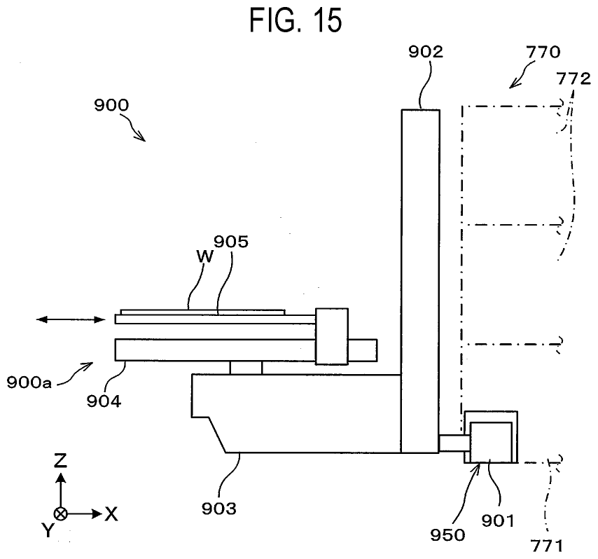

Further, as shown in FIG. 11, the processing station 703 of the coating-developing apparatus 1A includes a housing 770. The housing 770 accommodates the modules described above. Further, the housing 770 is partitioned into individual transfer regions. As shown in FIG. 15, the housing 770 includes a housing 771 that accommodates a guide 901, and the like, which will be described later.

As shown in FIGS. 11 and 15, the transfer mechanism 900 also includes the guide 901 extending in a length direction (the Y direction in FIG. 15, and the like) of the transfer regions R1 to R4, and the transfer arm 900a that supports the wafer W and moves the same in the horizontal directions (the X and Y directions in the figure), the vertical direction, and around the vertical axis (the 0 direction).

The transfer arm 900a includes a frame 902 that moves along the guide 901, an elevator 903 that moves up and down along the frame 902, and a base 904 that rotates relative to the elevator 903. The transfer arm 900a also includes a fork 905. The fork 905 is movably configured to support the wafer W and moves backward and forward relative to the base 904.

Further, the transfer mechanism 900 includes a drive mechanism (not shown) that linearly moves the fork 905 in the direction (the X direction in the figure) in which the fork 905 moves backward and forward relative to the base 904, and a drive mechanism (not shown) that rotates the base 904 relative to the elevator 903, that is, moves the same in the 0 direction. The transfer mechanism 900 also includes a drive mechanism (not shown) that raises and lowers the elevator 903 along the frame 902, and a drive mechanism 950 that moves the frame 902 along the guide 901.

The drive mechanism 950 includes the aforementioned guide 901, and further includes an actuator (not shown) such as a motor as a drive source that generates a driving force to move the frame 902 along the guide 901. The drive mechanism 950 is accommodated in the aforementioned housing 771. A housing 772 that accommodates the hot plate 401 of the heating module 24 and the like is stacked on the housing 771.

In the coating-developing apparatus 1A including the transfer mechanism 900 configured as above, when the setting of the processing temperature of the heating module 24 is changed, the housing 771 accommodating the guide 901 of the transfer mechanism 900 may be undergone thermal shrinkage due to the influence of the hot plate 401, which may cause deformation of the guide 901. As a result, the wafer W on the fork 905 moved to the delivery position may be decentered with respect to the spin chuck 201 of the resist film forming module 21.

Further, the method of adjusting the delivery position according the present disclosure may be applied to the delivery position of the fork 905 relative to the resist film forming module 21.

According to the present disclosure in some embodiments, it is possible to transfer a substrate to a target position with high accuracy.

The embodiments disclosed herein should be considered to be illustrative in all respects and not restrictive. The above-described embodiments may be omitted, substituted, or modified in various ways without departing from the scope and spirit of the appended claims. For example, constituent elements of the above embodiments may be arbitrarily combined. From this arbitrary combination, it is needless to say that the operations and effects of the respective constituent elements related to the combination may be obtained, and other operations and other effects obvious to those skilled in the art may be obtained from the description of the present specification.

Further, the effects described herein are illustrative or exemplary only and are not restrictive. That is, the technique of the present disclosure may obtain other effects obvious to those skilled in the art from the description herein in addition to or in place of the above effects.

Further, the following configurations belong to the technical scope of the present disclosure.
(1) A substrate transfer apparatus for transferring a substrate to a rotation processor provided in a housing provided in common with at least one heat treater configured to perform a heat treatment on the substrate and configured to perform processing on the substrate while holding and rotating the substrate. The substrate transfer apparatus includes a transfer arm configured to support and move the substrate, and a controller configured to control an operation of the transfer arm. The controller acquires first and second eccentric positions of the substrate held by the rotation processor with respect to a rotational center of the rotation processor based on maximum and minimum temperatures which are set as processing temperatures of the at least one heat treater, and adjusts a position of the transfer arm when delivering the substrate to the rotation processor based on the first eccentric position and the second eccentric position.
(2) In the substrate transfer apparatus of (1) above, the controller acquires an adjustment eccentric position based on the first eccentric position corresponding to the maximum temperature and the second eccentric position corresponding to the minimum temperature, and adjusts the position of the transfer arm when delivering the substrate based on the adjustment eccentric position.
(3) In the substrate transfer apparatus of (2) above, the adjustment eccentric position is a center of the first eccentric position corresponding to the maximum temperature and the second eccentric position corresponding to the minimum temperature.
(4) In the substrate transfer apparatus of (2) or (3) above, the first eccentric position corresponding to the maximum temperature is the eccentric position of the substrate available when the at least one heat treater is actually set to have the maximum temperature, and the second eccentric position corresponding to the minimum temperature is the eccentric position of the substrate available when the at least one heat treater is actually set to have the minimum temperature.
(5) In the substrate transfer apparatus of (4) above, the at least one heat treater includes a plurality of heat treaters provided in the housing,
the first eccentric position corresponding to the maximum temperature is the eccentric position of the substrate available when each of the plurality of heat treaters is actually set to have the maximum temperature, which may be set as a processing temperature of a respective heat treater, and
the second eccentric position corresponding to the minimum temperature is the eccentric position of the substrate available when each of the plurality of heat treaters is actually set to have the minimum temperature, which may be set as the processing temperature of the respective heat treater.
(6) In the substrate transfer apparatus of (1) above, the controller acquires an intermediate temperature between the maximum temperature and the minimum temperature, acquires a third eccentric position corresponding to the intermediate temperature, and adjusts the position of the transfer arm during transferring the substrate based on the third eccentric position corresponding to the intermediate temperature.
(7) In the substrate transfer apparatus of (6) above, the intermediate temperature is an average value of the maximum temperature and the minimum temperature.
(8) In the substrate transfer apparatus of (6) or (7) above, the third eccentric position corresponding to the intermediate temperature is the eccentric position of the substrate available when the at least one heat treater is actually set to have the intermediate temperature.
(9) In the substrate transfer apparatus of (8) above, the at least one heat treater includes a plurality of heat treaters provided in the housing, and
the third eccentric position corresponding to the intermediate temperature is the eccentric position of the substrate available when each of the plurality of heat treaters is actually set to have the intermediate temperature of a respective heat treater.
(10) A substrate transfer method of transferring a substrate, includes:
transferring, by a transfer arm, the substrate to a rotation processor provided in a housing provided in common with at least one heat treater configured to perform a heat treatment on the substrate and configured to perform processing on the substrate while holding and rotating the substrate,
wherein the transferring includes adjusting a position of the transfer arm when delivering the substrate to the rotation processor based on first and second eccentric positions of the substrate held by the rotation processor with respect to a rotational center of the rotation processor, the first and second eccentric positions being obtained based on maximum and minimum temperatures which are set as processing temperatures in the at least one heat treater.
(11) In the substrate transfer method of (10) above, the adjusting includes:
obtaining an adjustment eccentric position based on the first eccentric position corresponding to the maximum temperature and the second eccentric position corresponding to the minimum temperature; and
adjusting the position of the transfer arm when delivering the substrate based on the adjustment eccentric position.
(12) In the substrate transfer method of (11) above, the adjustment eccentric position is a center of the first eccentric position corresponding to the maximum temperature and the second eccentric position corresponding to the minimum temperature.
(13) In the substrate transfer method of (11) above, the first eccentric position corresponding to the maximum temperature is the eccentric position of the substrate available when the at least one heat treater is actually set to have the maximum temperature, and
wherein the second eccentric position corresponding to the minimum temperature is the eccentric position of the substrate available when the at least one heat treater is actually set to have the minimum temperature.
(14) In the substrate transfer method of (13) above, the at least one heat treater includes a plurality of heat treaters provided in the housing,
wherein the first eccentric position corresponding to the maximum temperature is the eccentric position of the substrate available when each of the plurality of heat treaters is actually set to have the maximum temperature, which is set as a processing temperature of a respective heat treater, and
wherein the second eccentric position corresponding to the minimum temperature is the eccentric position of the substrate available when each of the plurality of heat treaters is actually set to have the minimum temperature, which is set as the processing temperature of the respective heat treater.
(15) In the substrate transfer method of (10) above, the adjusting includes acquiring an intermediate temperature between the maximum temperature and the minimum temperature to obtain a third eccentric position corresponding to the intermediate temperature, and adjusting the position of the transfer arm during transferring the substrate based on the third eccentric position corresponding to the intermediate temperature.
(16) In the substrate transfer method of (15) above, the intermediate temperature is an average value of the maximum temperature and the minimum temperature.
(17) In the substrate transfer method of (15) or (16) above, the third eccentric position corresponding to the intermediate temperature is the eccentric position of the substrate available when the at least one heat treater is actually set to have the intermediate temperature.
(18) In the substrate transfer method of (17) above, the at least one heat treater includes a plurality of heat treaters provided in the housing, and
wherein the third eccentric position corresponding to the intermediate temperature is the eccentric position of the substrate available when each of the plurality of heat treaters is actually set to have the intermediate temperature of a respective heat treater.
(19) A non-transitory computer-readable storage medium storing a program that operates on a computer of a controller that controls a substrate transfer apparatus and causes the substrate transfer apparatus to execute a substrate transfer method,
wherein the substrate transfer method comprises transferring, by a transfer arm of the substrate transfer apparatus, a substrate to a rotation processor provided in a housing provided in common with at least one heat treater configured to perform a heat treatment on the substrate and configured to perform processing on the substrate while holding and rotating the substrate, and
wherein the transferring includes: adjusting a position of the transfer arm when delivering the substrate to the rotation processor based on first and second eccentric positions of the substrate held by the rotation processor with respect to a rotational center of the rotation processor, the first and second eccentric positions being obtained based on maximum and minimum temperatures which are set as processing temperatures in the at least one heat treater.

What is claimed is:

1. A substrate transfer apparatus for transferring a substrate to a rotation processor provided in a housing provided in common with at least one heat treater configured to perform a heat treatment on the substrate and configured to perform processing on the substrate while holding and rotating the substrate, the substrate transfer apparatus comprising:
a transfer arm configured to support and move the substrate; and
a controller configured to control an operation of the transfer arm,
wherein the controller acquires first and second eccentric positions of the substrate held by the rotation processor with respect to a rotational center of the rotation processor based on maximum and minimum temperatures which are set as processing temperatures of the at least one heat treater, and adjusts a position of the transfer arm when delivering the substrate to the rotation processor based on the first eccentric position and the second eccentric positions.

2. The substrate transfer apparatus of claim 1, wherein the controller acquires an adjustment eccentric position based on the first eccentric position corresponding to the maximum temperature and the second eccentric position corresponding to the minimum temperature, and adjusts the position of the transfer arm when delivering the substrate based on the adjustment eccentric position.

3. The substrate transfer apparatus of claim 2, wherein the adjustment eccentric position is a center of the first eccentric position corresponding to the maximum temperature and the second eccentric position corresponding to the minimum temperature.

4. The substrate transfer apparatus of claim 2, wherein the first eccentric position corresponding to the maximum temperature is the eccentric position of the substrate available when the at least one heat treater is actually set to have the maximum temperature, and
wherein the second eccentric position corresponding to the minimum temperature is the eccentric position of the substrate available when the at least one heat treater is actually set to have the minimum temperature.

5. The substrate transfer apparatus of claim 4, wherein the at least one heat treater includes a plurality of heat treaters provided in the housing,
wherein the first eccentric position corresponding to the maximum temperature is the eccentric position of the substrate available when each of the plurality of heat treaters is actually set to have the maximum temperature, which is set as a processing temperature of a respective heat treater, and
wherein the second eccentric position corresponding to the minimum temperature is the eccentric position of the substrate available when each of the plurality of heat treaters is actually set to have the minimum temperature, which is set as the processing temperature of the respective heat treater.

6. The substrate transfer apparatus of claim 1, wherein the controller acquires an intermediate temperature between the maximum temperature and the minimum temperature, acquires a third eccentric position corresponding to the intermediate temperature, and adjusts the position of the transfer arm during transferring the substrate based on the third eccentric position corresponding to the intermediate temperature.

7. The substrate transfer apparatus of claim 6, wherein the intermediate temperature is an average value of the maximum temperature and the minimum temperature.

8. The substrate transfer apparatus of claim 6, wherein the third eccentric position corresponding to the intermediate temperature is the eccentric position of the substrate available when the at least one heat treater is actually set to have the intermediate temperature.

9. The substrate transfer apparatus of claim 8, wherein the at least one heat treater includes a plurality of heat treaters provided in the housing, and
wherein the third eccentric position corresponding to the intermediate temperature is the eccentric position of the substrate available when each of the plurality of heat treaters is actually set to have the intermediate temperature of a respective heat treater.

10. A substrate transfer method of transferring a substrate, the method comprising:
transferring, by a transfer arm, the substrate to a rotation processor provided in a housing provided in common with at least one heat treater configured to perform a heat treatment on the substrate and configured to perform processing on the substrate while holding and rotating the substrate,
wherein the transferring includes:
adjusting a position of the transfer arm when delivering the substrate to the rotation processor based on first and second eccentric positions of the substrate held by the rotation processor with respect to a rotational center of the rotation processor, the first and second eccentric positions being obtained based on maximum and minimum temperatures which are set as processing temperatures of the at least one heat treater.

11. The substrate transfer method of claim 10, wherein the adjusting includes:
obtaining an adjustment eccentric position based on the first eccentric position corresponding to the maximum temperature and the second eccentric position corresponding to the minimum temperature; and
adjusting the position of the transfer arm when delivering the substrate based on the adjustment eccentric position.

12. The substrate transfer method of claim 11, wherein the adjustment eccentric position is a center of the first eccentric position corresponding to the maximum temperature and the second eccentric position corresponding to the minimum temperature.

13. The substrate transfer method of claim 11, wherein the first eccentric position corresponding to the maximum temperature is the eccentric position of the substrate available when the at least one heat treater is actually set to have the maximum temperature, and
wherein the second eccentric position corresponding to the minimum temperature is the eccentric position of the substrate available when the at least one heat treater is actually set to have the minimum temperature.

14. The substrate transfer method of claim 13, wherein the at least one heat treater includes a plurality of heat treaters provided in the housing,
wherein the first eccentric position corresponding to the maximum temperature is the eccentric position of the substrate available when each of the plurality of heat treaters is actually set to have the maximum temperature, which is set as a processing temperature of a respective heat treater, and
wherein the second eccentric position corresponding to the minimum temperature is the eccentric position of the substrate available when each of the plurality of heat treaters is actually set to have the minimum temperature, which is set as the processing temperature of the respective heat treater.

15. The substrate transfer method of claim 10, wherein the adjusting includes acquiring an intermediate temperature between the maximum temperature and the minimum temperature to obtain a third eccentric position corresponding to the intermediate temperature, and adjusting the position of the transfer arm during transferring the substrate based on the third eccentric position corresponding to the intermediate temperature.

16. The substrate transfer method of claim 15, wherein the intermediate temperature is an average value of the maximum temperature and the minimum temperature.

17. The substrate transfer method of claim 15, wherein the third eccentric position corresponding to the intermediate temperature is the eccentric position of the substrate available when the at least one heat treater is actually set to have the intermediate temperature.

18. The substrate transfer method of claim 17, wherein the at least one heat treater includes a plurality of heat treaters provided in the housing, and
wherein the third eccentric position corresponding to the intermediate temperature is the eccentric position of the substrate available when each of the plurality of heat treaters is actually set to have the intermediate temperature of a respective heat treater.

19. A non-transitory computer-readable storage medium storing a program that operates on a computer of a controller that controls a substrate transfer apparatus and causes the substrate transfer apparatus to execute a substrate transfer method,
wherein the substrate transfer method comprises transferring, by a transfer arm of the substrate transfer apparatus, a substrate to a rotation processor provided in a housing provided in common with at least one heat treater configured to perform a heat treatment on the substrate and configured to perform processing on the substrate while holding and rotating the substrate, and
wherein the transferring includes: adjusting a position of the transfer arm when delivering the substrate to the rotation processor based on first and second eccentric positions of the substrate held by the rotation processor with respect to a rotational center of the rotation processor, the first and second eccentric positions being obtained based on maximum and minimum temperatures which are set as processing temperatures of the at least one heat treater.
